(19) United States
(12) Patent Application Publication
(10) Pub. No.: US 2012/0107558 A1
(43) Pub. Date: May 3, 2012

(54) TRANSPARENT SUBSTRATE HAVING DURABLE HYDROPHOBIC/OLEOPHOBIC SURFACE

(76) Inventors: Shari Elizabeth Koval, Beaver Dams, NY (US); Jia Liu, Painted Post, NY (US); Prantik Mazumder, Ithaca, NY (US); Charlotte Diane Milia, Corning, NY (US); Mark Alejandro Quesada, Horseheads, NY (US); Wageesha Senaratne, Horseheads, NY (US); Todd Parrish St. Clair, Painted Post, NY (US)

(21) Appl. No.: 12/916,859

(22) Filed: Nov. 1, 2010

(51) Int. Cl. B32B 5/16; C23C 14/34; B05D 1/36; B82Y 30/00

(52) U.S. Cl. 428/142; 427/258; 427/269; 204/192.1; 977/773

(57) ABSTRACT

A substrate having a durable hydrophobic and/or oleophobic surface. The durable hydrophobic and/or oleophobic surface includes a first layer that is disposed on the substrate and comprises inorganic nanoparticles, an outer layer comprising a fluorosilane, and an optional immobilizing layer that comprises at least one of an inorganic oxide and a silsesquioxane. The durable surface is capable of retaining optical properties, such as haze, and hydrophobic and/or oleophobic properties after repeated contact with foreign objects such as, for example, wiping with a cloth or human finger.

### BACKGROUND

The disclosure relates to a transparent substrate having a durable surface that is hydrophobic and/or oleophobic. More particularly, the disclosure relates to such durable hydrophobic and/or oleophobic surfaces that are durable.

Surfaces having engineered nanostructures are used in applications where anti-glare and anti-reflective properties, low haze/transparency, and resistance to “fingerprinting” or wetting by water and/or sebaceous oils (e.g., by materials deposited by transferred from a user's finger) is desired. Such surfaces frequently include layers containing nanoparticles that provide desirable wetting and optical properties.

### SUMMARY

A transparent substrate having a durable hydrophobic and/or oleophobic surface is provided. The durable hydrophobic and/or oleophobic surface includes a first layer that is disposed on the transparent substrate and comprises inorganic nanoparticles, an outer layer comprising a fluorosilane, and an optional immobilizing layer that comprises at least one of an inorganic oxide and a silsesquioxane. The durable surface is capable of retaining optical properties, such as haze, and hydrophobic and/or oleophobic properties after repeated contact with foreign objects such as, for example, wiping with a cloth or human finger.

Accordingly, one aspect of the disclosure is to provide a transparent substrate having a durable surface that exhibits at least one of hydrophobicity and oleophobicity. The durable surface comprises: a first layer disposed on the transparent substrate, the first layer comprising inorganic nanoparticles having an average particle size and a first layer topography; and a fluorosilane coating disposed over the first layer, wherein the durable surface has one of an oil contact angle and a water contact angle after 100 wipes that varies by less than about 20% from an initial contact angle measured before wiping.

A second aspect of the disclosure is to provide a transparent substrate having a durable surface that exhibits at least one of hydrophobicity and oleophobicity. The durable surface comprises: a first layer of inorganic nanoparticles disposed on the substrate, the inorganic nanoparticles having a mean particle size; a immobilizing layer disposed over the first layer, wherein the immobilizing layer comprises at least one inorganic oxide and has a thickness that is within about 20% of the average particle size of the inorganic nanoparticles in the first layer; and a fluorosilane coating disposed over the immobilizing layer, wherein the durable surface has one of an oil contact angle and a water contact angle after 100 wipes that varies by less than about 20% from an initial contact angle measured before wiping.

A third aspect of the disclosure is to provide a transparent substrate having a durable surface that exhibits at least one of hydrophobicity and oleophobicity. The durable surface comprises: at least one layer disposed on the substrate comprising a plurality of inorganic nanoparticles and a silsesquioxane; and a fluorosilane coating disposed over the at least one layer, wherein the durable surface has one of an oil contact angle and a water contact angle after 100 wipes that varies by less than about 20% from an initial contact angle measured before wiping.

A fourth aspect of the disclosure is to provide a method of making a transparent substrate having a durable surface that exhibits at least one of hydrophobicity and oleophobicity. The method comprises the steps of: providing a transparent substrate; forming a first layer on a surface of the substrate, the first layer comprising a plurality of inorganic nanoparticles and having a topography; optionally forming an immobilizing layer on the first layer, the immobilizing layer comprising at least one of a silsesquioxane and an inorganic oxide; and forming an outer layer comprising a fluorosilane on one of the first layer and immobilizing layer to form the durable surface. The durable surface has one of an oil contact angle and a water contact angle after 100 wipes that varies by less than about 20% from an initial contact angle measured before wiping.

These and other aspects, advantages, and salient features will become apparent from the following detailed description, the accompanying drawings, and the appended claims.

### BRIEF DESCRIPTION OF THE DRAWINGS

FIG. 1 is a schematic cross-sectional view of a substrate having a durable surface;

FIG. 2a is a scanning electron microscopy (SEM) image of a cross-section of a glass substrate that was dip-coated in a dispersion of silica soot in water;

FIG. 2b is a SEM image of a cross-section of a glass substrate that was dip-coated in a colloidal dispersion of spherical silica particles in isopropyl alcohol;

FIG. 2c is a SEM image of a cross-section of a glass substrate of a glass substrate having a first layer comprising colloidal silica particles and silsesquioxane (SSQ);

FIG. 2d is a SEM image of a top view of a glass substrate of a glass substrate having a first layer comprising colloidal silica particles and SSQ;

FIG. 3 is a SEM image of a cross-section of a glass substrate having a first layer comprising ceria and an immobilizing layer comprising a tin-fluoro-phosphate glass material;

FIG. 4a is a SEM image of a top view of tin-fluoro-phosphate glass material that was sputtered directly onto an alkali aluminosilicate glass substrate;

FIG. 4b is a SEM image of a top view of an immobilizing layer comprising tin-fluoro-phosphate glass material that was sputtered onto a first layer of ceria and then annealed after deposition;

FIG. 4c is a SEM image of a top view of an immobilizing layer comprising tin-fluoro-phosphate glass material that was sputtered onto a first layer of ceria and left untreated after deposition; and

FIG. 4d is a SEM image of a top view of an immobilizing layer comprising tin-fluoro-phosphate glass material that was sputtered onto a first layer of ceria and then etched after deposition.

### DETAILED DESCRIPTION

In the following description, like reference characters designate like or corresponding parts throughout the several views shown in the figures. It is also understood that, unless otherwise specified, terms such as “top,” “bottom,” “outward,” “inward,” and the like are words of convenience and are not to be construed as limiting terms. In addition, whenever a group is described as comprising at least one of a group of elements and combinations thereof, it is understood that the group may comprise, consist essentially of, or consist of any number of those elements recited, either individually or in combination with each other. Similarly, whenever a group is described as consisting of at least one of a group of elements or combinations thereof, it is understood that the group may consist of any number of those elements recited, either individually or in combination with each other. Unless otherwise specified, a range of values, when recited, includes both the upper and lower limits of the range. As used herein, the indefinite articles “a,” “an,” and the corresponding definite article “the” means “at least one” or “one or more,” unless otherwise specified.

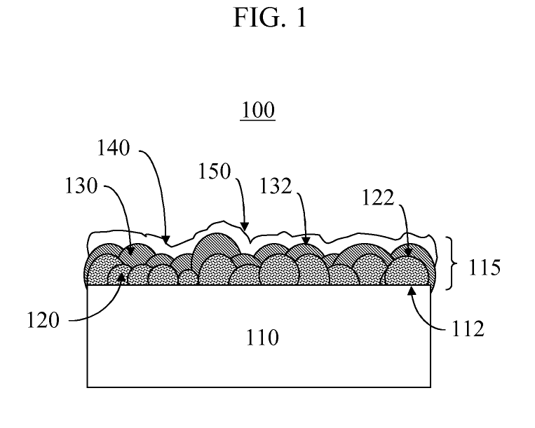

Referring to the drawings in general and to FIG. 1 in particular, it will be understood that the illustrations are for the purpose of describing particular embodiments and are not intended to limit the disclosure or appended claims thereto. The drawings are not necessarily to scale, and certain features and certain views of the drawings may be shown exaggerated in scale or in schematic in the interest of clarity and conciseness.

As used herein, the terms “contact angle” and “CA” refer to the angle tangent at the point where a liquid drop contacts a substrate. The term “substrate” as used herein includes, but is not limited to, glass articles, including windows, cover plates, screens, panels, and substrates that form the outer portion of a display screen, window, or structure for mobile electronic devices. When used to describe a substrate and wetting characteristics of said substrate, the terms “hydrophobic” and “hydrophobicity” refer to the state in which the contact angle between a substrate and a water droplet is greater than 90°, and the terms “superhydrophobic” and “superhydrophobicity” refer to a state in which the contact angle between a substrate and a water droplet is greater than 150°. Similarly, the terms “oleophobic” and “oleophobicity” refer to a state in which the contact angle between a substrate and an oil droplet is greater than 90° and the terms “oleophobic” and “oleophobicity” refer to a state which the contact angle between a substrate and an oil droplet is greater than 150°.

It has been discovered that surfaces having nanoengineered structures lack durability due to removal of the nanoparticles by repeated contact of the surface with foreign objects such as, for example, a cloth or human finger. Accordingly, a transparent substrate having a durable surface that is hydrophobic, oleophobic, or both is provided. The durable surface includes a first layer that comprises inorganic nanoparticles and a fluorosilane outer coating over the first layer. A schematic cross-sectional view of the substrate is shown in FIG. 1. Hydrophobic and/or oleophobic substrate 100 has a durable surface 115 that comprises a first layer 120 disposed on a surface 112 of substrate 110 and an outer layer or coating 140 comprising a fluorosilane. Durable surface 115 has an outer surface 150 opposite surface 112 of substrate 110, wherein outer surface 150 of durable surface 115 has a topography and/or profile that is substantially conformal with the topography/profile the outer surface 122 of first layer 120. As used herein, the terms “conformal” and “substantially conforms with” means that the topography and/or profile features of outer surface 150 largely or mostly (i.e., greater than about 50%) match, follow, or correspond to those topographical/profile shapes and features of outer surface 122 of first layer 120, as evidenced by outer surface 150 having substantially the same RMS roughness, autocorrelation, periodicity, and/or fractal dimension as outer surface 122 of first layer 120. In some embodiments, outer surface 150 has substantially the same RMS roughness, autocorrelation, periodicity, and/or fractal dimension that are within about 30% of those of outer surface 122 of first layer 120.

The first layer 120 comprising inorganic nanoparticles has an outer surface 122 that provides the substrate with a surface roughness and topography that enhances the hydrophobicity and/or oleophobicity of the surface of the substrate. The presence of surface roughness and/or topography (e.g., protrusions, depressions, grooves, pore, pits, voids, and the like) can alter the contact angle between a given fluid (or fluid droplet) and a flat substrate, and is frequently referred to as the “lotus leaf” or “lotus” effect. The wetting behavior of liquids on a roughened solid surface can be described by either the Wenzel (low contact angle) model or the Cassie-Baxter (high contact angle) model. In the Wenzel model, a fluid droplet on a roughened solid surface penetrates free space such as pits, holes, grooves, pores, voids and the like, on the roughened solid surface, causing the droplet to become “pinned” on the roughened surface. The Wenzel model takes into account the increase in interface area of a roughened solid surface relative to a smooth surface and predicts that, when smooth surfaces are hydrophobic or oleophobic, roughening such surfaces will further increase their hydrophobicity and/or oleophobicity. Conversely, when smooth surfaces are hydrophilic or oleophilic, the Wenzel model predicts that roughening such surfaces will further increase their hydrophilic and/or oleophilic behavior. In contrast to the Wenzel model, the Cassie-Baxter model predicts that surface roughening always increases the contact angle θ_{Y} of a fluid droplet, regardless of whether the smooth solid surface is hydrophilic or hydrophobic. The Cassie-Baxter model describes the case in which gas pockets are formed in the free space of a roughened solid surface and are trapped beneath the fluid droplet, thus preventing a decrease in contact angle θ_{Y} and pinning of fluid droplets on (or in) the surface. When pressure, such as that applied by a human finger, is applied to a fluid droplet, the fluid droplet can penetrate the free space in the roughened surface and become pinned—i.e., the fluid droplet transitions from the Cassie-Baxter state to the Wenzel state. A substrate that is hydrophobic and/or oleophobic, or is resistant to fingerprinting, should provide a lotus leaf effect and thus maintain fluid droplets in the Cassie-Baxter state; i.e., the state in which gas pockets are trapped beneath fluid droplets on a roughened solid surface and pinning of the fluid droplets is avoided. In addition, such surfaces should, to some degree, prevent or retard a decrease in contact angle θ_{Y} and the transition to the Wenzel state when pressure is applied to the fluid droplets.

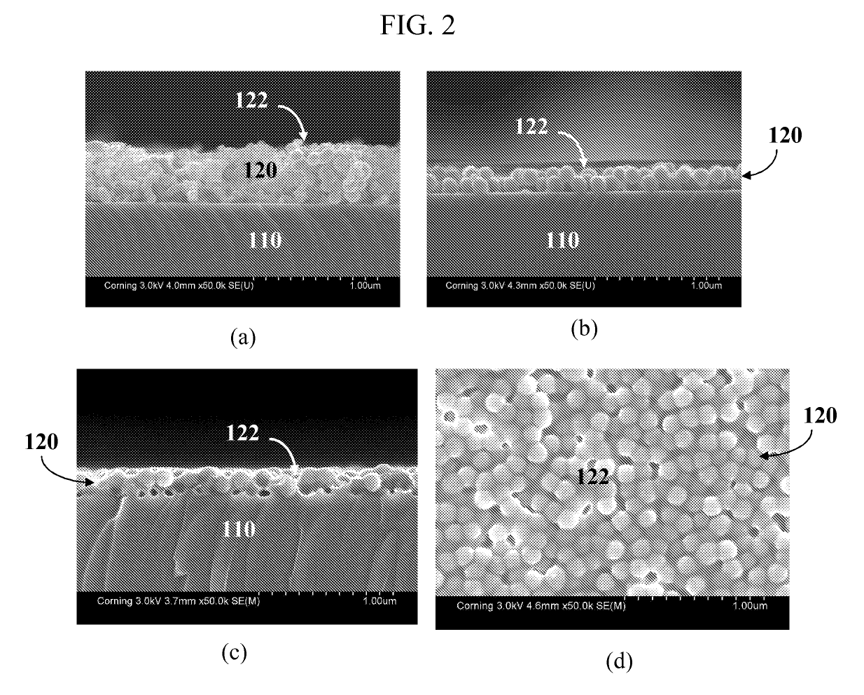

The inorganic nanoparticles in the first layer 120, in some embodiments, comprise inorganic oxides such as, but not limited to, ceria (CeO₂), zinc oxide (ZnO), alumina (Al₂O₃), silica (SiO₂) soot, colloidal silica spheres or spherical particles, or the like. Alternatively, the inorganic nanoparticles may comprise inorganic sulfides and selenides. First layer 120 has a surface 122 that has a topography and/or roughness that enhances the hydrophobicity and/or oleophobicity of the durable surface 115. The first layer 120 can be formed by applying a dispersion or slurry comprising the nanoparticles to the surface 112 of substrate 110 by at least one of spin-coating, spray-coating, or dip-coating the substrate 100 with—the dispersion or slurry. Such coating processes may be repeated multiple times to obtain the desired thickness of first layer 120. FIGS. 2a and 2b are scanning electron microscopy (SEM) images of cross-sections of alkali aluminosilicate glass substrates 110 having a first layer 120 of silica (SiO₂) soot and spherical silica particles, respectively. The glass substrate shown in FIG. 2a was dip-coated in a dispersion of 5 wt % silica soot in water. The average SiO₂ soot aggregate size varied from 150 nm to 250 nm and produced a high void dip-coated first layer 120 having a non-uniform thickness. The glass substrate shown in FIG. 2b was dip-coated in a colloidal dispersion of 5 wt % spherical silica particles in isopropyl alcohol. The colloidal particles had an average size ranging from 70 nm to 100 nm and formed a mono- or bi-layer first layer 120 of uniform thickness. The cross-sectional views of first layer 120 in FIGS. 2a-b show the roughened, irregular outer surface 122 of first layer 120 in profile.

In one embodiment, the first layer 120 can further include a resin binder having a cage-like structure. Non-limiting examples of such resins include silsesquioxanes (SSQs) and the like. As used herein, the term “silsesquioxane” refers to compounds having the empirical chemical formula RSiO_{1.5}, where R is either hydrogen or an alkyl, alkene, aryl, or arylene group. In such instances, the resin binder is mixed into the dispersion or slurry comprising the inorganic nanoparticles, which is then applied to the substrate 110 as described hereinabove. The first layer/coating 120 is then heat treated to crosslink the resin around the inorganic nanoparticles. In one embodiment, the first layer/coating 120 is heat-treated at a temperature of about 300° C. and, in some embodiments, in a range from about 250° C. up to about 350° C., wherein the resin cage structure is converted to a network structure. In another embodiment, the first layer/coating 120 is heated or annealed at a temperature of at least about 350° C., wherein the SSQ resin structure is converted to silica via thermal dissociation of Si—H with no affect on the SiO₂ nanoparticles. SEM images of cross-sectional and top views of fractured alkali aluminosilicate glass substrates having a first layer 120 comprising colloidal silica spherical particles and SSQ are shown in FIGS. 2c and 2d, respectively. To obtain the first layer 120 shown in FIGS. 2c and 2d, a mixture comprising 5 wt % colloidal silica particles and 17 wt % SSQ was spin coated onto the substrate 110 and annealed at 300° C. for 1 hour. While some thickness variation is first layer 120 seen across the sample, the dip-coated mixture exhibited good adhesion between silica particles as well as between the silica particles and the glass surface through the SSQ resin. The cross-sectional view of first layer 120 in FIG. 2c shows the roughened, irregular outer surface 122 of first layer 120 in profile. The top view (FIG. 2d) of first layer 120 shows the irregular, roughened surface topography of surface 122.

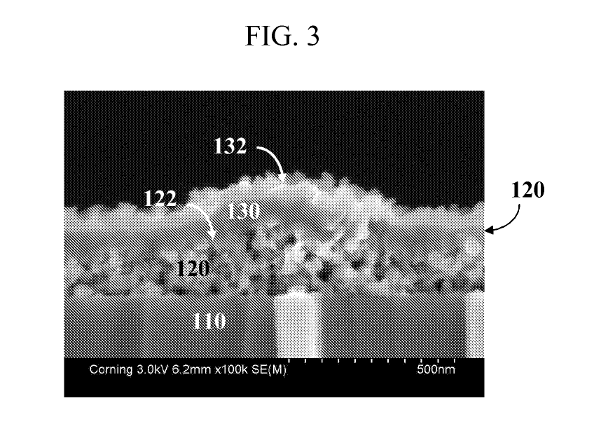

In some embodiments, the durable surface 115 further includes an immobilizing layer 130 or coating disposed between the first layer 120 and the fluorosilane outer layer 140 or coating. The immobilizing layer 130 “immobilizes”—i.e., fixes and preserves—the topography of the first layer 120 and provides durability for the topography of outer surface 122 of first layer 120. Immobilizing layer 130 comprises at least one inorganic oxide such as, but not limited to, zirconia (ZrO₂), tin oxide (SnO₂), SiO, and SiO₂. In one embodiment, the immobilizing layer 130 comprises a sputtered inorganic oxide layer such as, for example, a tin-fluoro-phosphate glass material which, in some embodiments, may be subsequently annealed or etched. A SEM image (100× magnification) of a cross-sectional view of an alkali aluminosilicate glass substrate having a first layer 120 and immobilizing layer 130 is shown in FIG. 3. The substrate 110 shown in FIG. 3 was dip-coated with a 5 wt % aqueous dispersion of agglomerated CeO₂ nanoparticles having an average agglomerate size of 160 nm and air-dried to form first layer 120. The immobilizing layer 130, comprising a tin-fluoro-phosphate glass material, was formed by sputtering, and had a thickness of 177 nm. Immobilizing layer 130 has an outer surface 132 that has a topography and/or profile that substantially conforms or corresponds to that of surface 122 of first layer 120. As used herein “substantially conforms to” means that the topography and/or profile features of outer surface 132 of immobilizing layer 130 largely or mostly (i.e., greater than 50%) conforms, adapts, and/or corresponds to those topographical/profile features of outer surface 122 of first layer 120, as evidenced by outer surface 132 having substantially the same RMS roughness, autocorrelation, periodicity, and/or fractal dimension as outer surface 122 of first layer 120. In some embodiments, outer surface 132 of immobilizing layer 130 has substantially a RMS roughness, autocorrelation, periodicity, and/or fractal dimension that are within about 30% of those of outer surface 122 of first layer 120. As seen in FIG. 3, the profile of outer surface 132 of intermediate layer 130 substantially conforms to that of outer layer 122 of first layer 120, following the increases and decreases in thickness of first layer 120.

In some embodiments, the sputtered inorganic oxide immobilizing layer 130 has a thickness that is within about 20% of the average aggregate or particle size of the plurality of nanoparticles in the first layer 120. Here, the immobilizing layer 130 is “tuned” (i.e., is deposited or otherwise adjusted by etching, grinding, polishing, or the like to achieve a selected or predetermined thickness) to be thick enough to promote adhesion, but sufficiently thin so as to have a minimal impact on the wetting behavior of the topography of outer surface 122 of first layer 120. The first layer 120 can be completely sealed when adsorbed atoms or molecules coalesce to form the immobilizing layer 130, or when the immobilizing layer 130 has a thickness of about 50 nm. However, the thickness of the immobilizing layer 130 should be sufficiently controlled so that the deposited immobilizing layer 130 does not obscure the wetting properties, topography, and/or profile of outer surface 122 of first layer 120 and thus dominate the overall wetting properties of the durable surface 115.

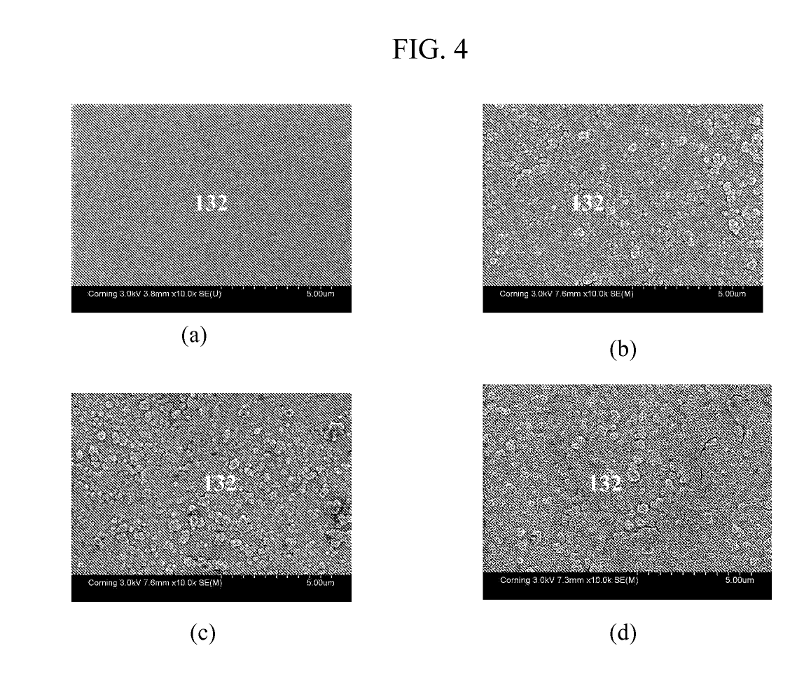

FIGS. 4b-d are SEM images of aluminosilicate glass substrate surfaces having an immobilizing layer 130 with thicknesses that approximate or are similar to the average agglomerate or average particle size of CeO₂ nanoparticles in the first layer 120. FIG. 4a is a SEM image of a top view of tin-fluoro-phosphate glass material that was sputtered directly onto a surface of an alkali aluminosilicate glass substrate. In the absence of topography provided by first layer 120, the topography of surface 132 of immobilizing layer 130 is relatively smooth. In the samples shown in FIGS. 4b-d, immobilizing layer 130 consists of sputtered tin-fluoro-phosphate glass material that has either been annealed (FIG. 4b), untreated (i.e., the sputtered surface is not subsequently annealed or etched) (FIG. 4c), or etched (FIG. 4d) after deposition. When compared with the glass substrate surface onto which tin-fluoro-phosphate glass material was directly sputtered (FIG. 4a), the rough topography of surface 132 of immobilizing layer 130 is apparent in FIGS. 4b-d. The rough topography of surface 132 conforms to the topography of the dip-coated outer surface 122 of the underlying first layer 120. The annealed surface (FIG. 4b) of immobilizing layer 130 is not as rough as the untreated surface (FIG. 4c), but exhibits a durability that is similar to that of the untreated second surface (FIG. 4a). The etched surface (FIG. 4d) of surface 132 of immobilizing layer 130 is pockmarked and therefore structurally weakened.

In other embodiments, the immobilizing layer 120 comprises a silsesquioxane coating that can be applied by spin-coating, spray-coating, or dip-coating the substrate 110 with a SSQ solution after application, drying and/or curing of the first layer 120. Multiple coating steps can be performed to provide the substrate 110 with an amount of SSQ sufficient to form an immobilizing layer 130 that backfills and completely covers the first layer 120. Following application of the immobilizing layer 130, the surface is then heat treated at a temperature in a range from about 300° C. up to about 550° C. In one embodiment, the temperature is sufficient to cross-link the SSQ resin and is in a range from about 300° C. up to about 350° C. In another embodiment, the surface is heated at a temperature (typically about 550° C.) that is sufficient to convert the silsesquioxane to silica.

The immobilizing layer 130 and/or the addition of silsesquioxane to the first layer 120, as described herein, allow the hydrophobic and/or oleophobic properties that are provided by the topography of the first layer 120 to be retained when wiped with a cloth, such as in the 100-wipe crockmeter test described herein.

The fluorosilane outer coating 140 comprises a low surface energy polymer or oligomer such as, but not limited to, Teflon™ or other commercially available fluoropolymers or fluorosilanes such as Dow Corning 2604, 2624, 2634, DK Optool DSX, Shintesu OPTRON, heptadecafluoro silane (Gelest), FluoroSyl (Cytonix), and the like. The fluorosilane coating is applied by one of spin-coating, spray-coating, or dip-coating. Alternatively, the fluorosilane coating can be deposited by sputtering or other physical or chemical vapor deposition techniques.

The embodiments in which silsesquioxane resin is included in the first layer 120 and the embodiments in which the surface topographies of the first layer 120 are combined with a SSQ-containing immobilizing layer 130 as described herein provide the durable surface 110 of the hydrophobic and/or oleophobic substrate 100 with enhanced durability when rubbed with a fabric or other instrument such as, for example, a human finger, or when exposed to chemical abrasion such as attack by acids or bases. Coating durability (also referred to as Crock Resistance) refers to the ability of the hydrophobic and/or oleophobic substrate 100 to withstand repeated rubbing with a cloth. The Crock Resistance test is meant to mimic the physical contact between garments or fabrics with a touch screen device and to determine the durability of the coatings disposed on the substrate after such treatment.

A Crockmeter is a standard instrument that is used to determine the Crock resistance of a surface subjected to such rubbing. The Crockmeter subjects a glass slide to direct contact with a rubbing tip or “finger” mounted on the end of a weighted arm. The standard finger supplied with the Crockmeter is a 15 mm diameter solid acrylic rod. A clean piece of standard crocking cloth is mounted to this acrylic finger. The finger then rests on the sample with a pressure of 900 g and the arm is mechanically moved back and forth repeatedly across the sample in an attempt to observe a change in the durability/crock resistance. The Crockmeter used in the tests described herein is a motorized model that provides a uniform stroke rate of 60 revolutions per minute. The Crockmeter test is described in ASTM test procedure F1319-94, entitled “Standard Test Method for Determination of Abrasion and Smudge Resistance of Images Produced from Business Copy Products,” the contents of which are incorporated herein by reference in their entirety.

Crock resistance or durability of the coatings, surfaces, and substrates described herein is determined by optical (e.g., haze or transmittance) or chemical (e.g., water and/or oil contact angle) measurements after a specified number of wipes as defined by ASTM test procedure F1319-94. A “wipe” is defined as two strokes or one cycle, of the rubbing tip or finger. In one embodiment, after 100 wipes the contact angle of oil on the durable surfaces 115 of the hydrophobic and/or oleophobic substrate 100 described herein varies by less than about 20% from an initial contact angle value of oil on the surface measured before wiping. In some embodiments, after 1000 wipes the contact angle of oil on the durable surfaces 115 varies by less than about 20% from the initial contact angle value and, in other embodiments, after 5000 wipes the contact angle of oil on the durable surfaces 115 varies by less than about 20% from the initial contact angle value. Similarly, the contact angle of water on the hydrophobic and/or oleophobic substrates 100 described herein, after 100 wipes, varies by less than about 20% from an initial contact angle value of water on the surface, measured before wiping. In other embodiments, the contact angle of water on the durable surface 115 of the substrate 100, after 1000 wipes, varies by less than about 20% from the initial contact angle value and, in other embodiments, after 5000 wipes varies by less than about 20% from the initial contact angle value initial value.

The durable surfaces 115 and transparent hydrophobic and/or oleophobic glass substrates 100 described herein also retain a low level of haze after such repeated wiping. In one embodiment, the durable surfaces 115 and transparent hydrophobic and/or oleophobic glass substrates 100 described herein The durable surface 115 of hydrophobic and/or oleophobic substrate 100 described herein have a haze, as defined by ASTM test procedure F1319-94, of less than about 80%, in other embodiments, less than 50% and, in still other embodiments, less than about 10%.

The hydrophobic and/or oleophobic glass substrates 100 and, particularly, durable surface 115, described herein are also resistant to fingerprinting. As used herein, the terms “anti-fingerprint,” “anti-fingerprinting,” and “fingerprint resistant” refer to the resistance of a surface to the transfer of fluids and other materials found in human fingerprints; the non-wetting properties of a surface with respect to such fluids and materials; the minimization, hiding, or obscuring of human fingerprints on a surface, and combinations of such factors. Fingerprints comprise both sebaceous oils (e.g. secreted skin oils, fats, and waxes), debris of dead fat-producing cells, and aqueous components. Combinations and/or mixtures of such materials are also referred to herein as “fingerprint materials.” An anti-fingerprinting surface must therefore be resistant to both water and oil transfer when touched by a finger of a user. The wetting characteristics of such a surface are therefore such that the surface is both hydrophobic and oleophobic.

In one embodiment, the amount of fingerprint materials transferred from a human finger to the fingerprint resistant, durable surfaces 115 of the hydrophobic and/or oleophobic substrates 100 described herein is less than about 0.02 mg per touch of a human finger. In another embodiment, less than 0.01 mg per touch of such materials is transferred. In yet another embodiment, less than about 0.005 mg per touch of such materials is transferred. The area of the durable surface 115 covered by the droplets transferred per finger touch is less than about 20% and, in one embodiment, less than about 10% of the total area of the durable surface 115 of the hydrophobic and/or oleophobic substrate 100 contacted by a human finger.

As used herein, the terms “haze” and “transmission haze” refer to the percentage of transmitted light scattered outside an angular cone of ±4.0° in accordance with ASTM procedure D1003, the contents of which are incorporated herein by reference in their entirety. For an optically smooth surface, transmission haze is generally close to zero. The durable surface 115 of hydrophobic and/or oleophobic transparent substrate 100 described herein has a haze of less than about 80% after 100 wipes of durable surface 115. In a second embodiment, the durable surface 115 of hydrophobic and/or oleophobic transparent substrate 100 has a transmission haze of less than about 50% after 100 wipes of durable surface 115 and, in a third embodiment, the transmission haze of the surface is less than about 10% after 100 wipes of durable surface 115. In some embodiments, the transmittance of transparent substrate is greater than about 70% after 100 wipes of durable surface 115.

As used herein, the term “gloss” refers to the measurement of specular reflectance calibrated to a standard (such as, for example, a certified black glass standard) in accordance with ASTM procedure D523, the contents of which are incorporated herein by reference in their entirety. The durable surface 115 of the hydrophobic and/or oleophobic surfaces 100 described herein has a gloss (i.e.; the amount of light that is specularly reflected from sample relative to a standard at 60) of greater than about 60%.

In some embodiments, the transparent hydrophobic and/or oleophobic substrate 100 comprises a glass. The glass may, for example, be a soda lime glass or any glass that can be down-drawn, such as, but not limited to, alkali aluminosilicate glasses or alkali aluminoborosilicate glasses. In one embodiment, the alkali aluminosilicate glass comprises alumina, at least one alkali metal and, in some embodiments, greater than 50 mol %, SiO₂, in other embodiments, at least 58 mol %, and in still other embodiments, at least 60 mol % SiO₂, wherein the ratio

$$\frac{{Al}_{2} {O}_{3} ( mol \% ) + {B}_{2} {O}_{3} ( mol \% )}{\sum alkali metal modifiers ( mol \% )} > 1 ,$$

where the modifiers are alkali metal oxides. This glass, in particular embodiments, comprises, consists essentially of, or consists of: about 58 mol % to about 72 mol % SiO₂; about 9 mol % to about 17 mol % Al₂O₃; about 2 mol % to about 12 mol % B₂O₃; about 8 mol % to about 16 mol % Na₂O; and 0 mol % to about 4 mol % K₂O, wherein the ratio

$$\frac{{Al}_{2} {O}_{3} ( mol \% ) + {B}_{2} {O}_{3} ( mol \% )}{\sum alkali metal modifiers ( mol \% )} > 1 ,$$

where the modifiers are alkali metal oxides. In another embodiment, the alkali aluminosilicate glass comprises, consists essentially of, or consists of: about 61 mol % to about 75 mol % SiO₂; about 7 mol % to about 15 mol % Al₂O₃; 0 mol % to about 12 mol % B₂O₃; about 9 mol % to about 21 mol % Na₂O; 0 mol % to about 4 mol % K₂O; 0 mol % to about 7 mol % MgO; and 0 mol % to about 3 mol % CaO. In yet another embodiment, the alkali aluminosilicate glass substrate comprises, consists essentially of, or consists of: about 60 mol % to about 70 mol % SiO₂; about 6 mol % to about 14 mol % Al₂O₃; 0 mol % to about 15 mol % B₂O₃; 0 mol % to about 15 mol % Li₂O; 0 mol % to about 20 mol % Na₂O; 0 mol % to about 10 mol % K₂O; 0 mol % to about 8 mol % MgO; 0 mol % to about 10 mol % CaO; 0 mol % to about 5 mol % ZrO₂; 0 mol % to about 1 mol % SnO₂; 0 mol % to about 1 mol % CeO₂; less than about 50 ppm As₂O₃; and less than about 50 ppm Sb₂O₃; wherein 12 mol %≦Li₂O+Na₂O+K₂O≦20 mol % and 0 mol %≦MgO+CaO≦10 mol %. In still another embodiment, the alkali aluminosilicate glass comprises, consists essentially of, or consists of: about 64 mol % to about 68 mol % SiO₂; about 12 mol % to about 16 mol % Na₂O; about 8 mol % to about 12 mol % Al₂O₃; 0 mol % to about 3 mol % B₂O₃; about 2 mol % to about 5 mol % K₂O; about 4 mol % to about 6 mol % MgO; and 0 mol % to about 5 mol % CaO, wherein: 66 mol %≦SiO₂+B₂O₃+CaO≦69 mol %; Na₂O+K₂O+B₂O₃+MgO+CaO+SrO>10 mol %; 5 mol %≦MgO+CaO+SrO≦8 mol %; (Na₂O+B₂O₃)−Al₂O₃≦2 mol %; 2 mol %≦Na₂O−Al₂O₃≦6 mol %; and 4 mol %≦(Na₂O+K₂O)−Al₂O₃≦10 mol %.

In some embodiments, the glass is free of lithium, whereas in other embodiments, such glasses are free of at least one of arsenic, antimony, and barium. In some embodiments, the substrate is down-drawn, using methods such as, but not limited to fusion-drawing, slot-drawing, re-drawing, and the like.

The transparent hydrophobic and/or oleophobic glass substrate 100 is, in some embodiments, chemically or thermally strengthened before forming the durable surface 115 described herein. The strengthened substrate has at least one surface strengthened surface layer extending from a surface to a depth of layer below the surface. The strengthened surface layers are under compressive stress, whereas a central region of the glass substrate is under tension, or tensile stress, so as to balance forces within the glass. In thermal strengthening (also referred to herein as “thermal tempering”), the substrate is heated up to a temperature that is greater than the strain point of the glass but below the softening point of the glass and rapidly cooled to a temperature below the strain point to create strengthened layers at the surfaces of the glass substrate prior to formation of the first layer 120, optional immobilizing layer 130, and outer fluorosilane coating 140. In another embodiment, the glass substrate can be strengthened chemically by a process known as ion exchange. In this process, ions in the surface layer of the glass are replaced by—or exchanged with—larger ions having the same valence or oxidation state. In those embodiments in which the transparent hydrophobic and/or oleophobic substrate 100 comprises an alkali aluminosilicate or an alkali aluminoborosilicate glass, ions in the surface layer of the glass and the larger ions are monovalent alkali metal cations, such as Li⁺ (when present in the glass), Na⁺, K⁺, Rb⁺, and Cs⁺. Alternatively, monovalent cations in the surface layer may be replaced with monovalent cations other than alkali metal cations, such as Ag⁺, Tl⁺, Ci⁺, or the like.

Ion exchange processes typically comprise immersing a glass article in an ion exchange bath such as, for example, a molten salt bath containing the larger ions to be exchanged with the smaller ions in the glass. Parameters for the ion exchange process including, but not limited to, bath composition and temperature, immersion time, the number of immersions of the glass in a salt bath (or baths), use of multiple salt baths, additional steps such as annealing, washing, and the like, are generally determined by the composition of the glass and the desired depth of layer and compressive stress of the glass to be achieved by the strengthening operation. By way of example, ion exchange of alkali metal-containing glasses may be achieved by immersion in at least one molten salt bath containing a salt such as, but not limited to, nitrates, sulfates, and chlorides of the larger alkali metal ion. The temperature of the molten salt bath typically is in a range from about 380° C. up to about 450° C., while immersion times range from about 15 minutes up to about 16 hours. However, temperatures and immersion times different from those described above may also be used. Such ion exchange treatments typically result in strengthened alkali aluminosilicate or alkali aluminoborosilicate glasses having depths of layer ranging from about 10 μm up to at least about 50 μm with a compressive stress ranging from about 200 MPa up to about 800 MPa, and a central tension of less than about 100 MPa.

The glass substrate described herein may be used as a protective cover glass or window for display and touch applications, such as, but not limited to, hand-held or portable communication and entertainment devices such as telephones, music players, video players, or the like; and as display screens or touch sensor devices for information-related terminals (IT) (e.g., portable or laptop computers) devices; as well as in other applications.

### EXAMPLES

The following examples illustrate the various features and advantages of the disclosure and are in no way intended to limit the disclosure or appended claims thereto.

### Example 1

The following example describes formation of a substrate having a first layer comprising ceria nanoparticles, a sputtered glass immobilizing layer, and a fluorosilane outer layer. Alkali aluminosilicate glass substrates were dip-coated with a 5 wt % aqueous dispersion of CeO₂ nanoparticles having an average particle size of 160 nm and air-dried to form a first layer on the substrate. An immobilizing layer comprising a tin-fluoro-phosphate glass material was formed on the first layer by sputtering. All samples were then coated with Dow-Corning DC2634 fluorosilane.

The sputtered glass films had thicknesses within three different ranges: 50-60 nm; 170-180 nm; and 270-280 nm. The first thickness range (50-60 nm) approximates the condition in which cluster and grain growth or near-island coalescence occurs in the deposited film. The second thickness range (170-180 nm) is approximately equal to the average particle size of the CeO₂ particles in the first dip-coated layer that provide the surface topography for durable surface 115. The third thickness range (270-280) is approximately equal to twice the average particle size of the CeO₂ particles.

Dip coated and sputtered samples having the same thickness were either left untreated (“as-is”), etched in 3 M HCl for one minute), or annealed at 180° C. for 15 minutes. Oil and water contact angles were then measured for the treated (dip-coated, sputtered, and fluorosilane coated) surfaces of all samples. The samples were then subjected to 100 crockmeter wipes, and the water contact angles were re-measured. Results of the contact angle measurements obtained for the various sets of samples are listed in Table 1. The contact angles reported in Table 1 are averaged values of 5 independent contact angle measurements, with an experimental error of ±2-3°.

TABLE 1
Contact angle measurements obtained for glass substrates having
a dip-coated CeO₂ first layer, sputtered glass immobilizing layer,
and fluorosilane outer layer.

| | | | Contact angle (degrees) | | |
|---|---|---|---|---|---|
| | | | | | Water |
| Thickness | | | | | Post |
| (nm) | Sample | Treatment | Water | Oil | 100 wipes |
| 50-60 nm | 1 | Untreated | 136 | 97 | 109 |
| | 2 | Annealed | 140 | 99 | 111 |
| | 3 | Etched | 137 | 100 | 94 |
| 170-180 nm | 4 | Untreated | 134 | 90 | 128 |
| | 5 | Annealed | 133 | 93 | 127 |
| | 6 | Etched | 144 | 104 | 98 |
| 270-280 nm | 7 | Untreated | 132 | 92 | 128 |
| | 8 | Annealed | 130 | 86 | 119 |
| | 9 | Etched | 129 | 188 | 124 |

The water contact angles for samples having sputtered glass film thicknesses in the 170-180 nm and 270-280 nm ranges after 100 crockmeter wipes remained high, with the thicknesses nearest the average particle size of the CeO₂ particles in the dip-coated retaining high contact angles after 100 crockmeter wipes. Samples having sputtered film thicknesses in the 170-180 nm range exhibited only a 4%-5% loss of contact angle resulted from repeated swiping of the annealed and untreated samples (samples 4 and 5). Although etched samples exhibited clearly superior contact angles (sample 6, with 104° oil CA) before crockmeter wipes, the surface was more easily damaged, as reflected in the 32% decrease in H₂O contact angle after 100 wipes. The thin film thicknesses in the first range (50-60 nm) approximating near island coalescence (samples 1-3) initially exhibited high contact angles, but experienced about a 30% loss in contact angle after crockmeter swiping. Samples having the greatest film thicknesses (third range, 270-280 nm, samples 7, 8, 9) yielded results that were indistinguishable from glass substrates having only sputtered glass films, indicating that the sputtered film thickness in these samples was sufficient to obscure the topography of the underlying dip-coated CeO₂ layer and thus eliminate any advantage in wetting properties provided by the ceria layer.

### Example 2

This example demonstrates the contact angles and durability of first layers comprising different silica nanoparticles/dispersions in the absence of silsesquioxanes, and silsesquioxane layers in the absence of the underlying layer comprising silica nanoparticles. The processes that were used to affix silica particles to the surface of alkali aluminosilicate glass substrates are described as follows. Three different types of silica dispersions were prepared, and water and oil contact angles measured after treatment of the surfaces comprising the silica particles with a fluorosilane coating were measured. Experimental parameters, including silica dispersions, silica particle size, silica dispersion dipping speed, post dipping heat treatment, water contact angle (CA), oil CA, and film or coating thickness are listed in Table 2.

In one process, silica soot (SiO₂, ox-40 Degussa Chemical) was dispersed in an alkaline solution. Dispersions of 2.5, 5, and 10 wt % silica soot were dip-coated onto glass substrates at rates of 25 and 100 mm/min. A SEM image of the coating is shown in FIG. 2a. Water contact angles measured for samples varied from 150° to 170°, and oil contact angles varied from 110° to 122° for different dispersions. Haze values for the coatings ranged from 6% to 9%, and transmission ranged from 93% to 94%.

In another process, silica soot (SiO₂-catpoly, Degussa) was dispersed using a cationic polymer and dip-coated onto glass substrates. These films exhibited water and oil contact angles of greater than 140° and 120°, respectively. Haze levels were less than 5% with transmissions ranging from 93% to 94%.

In a third process, colloidal silica coatings were prepared by dip-coating colloidal dispersions of spherical silica particles having average sizes of 40-50 nm (30% ST-L, Nissan chemical) and 70-120 nm (30% ST-ZL, Nissan Chemical) in isopropyl alcohol (IPA) onto glass substrates. Data shown in Table 2 is for the 5 and 30 wt % 40-50 nm and 70-120 nm colloidal silica systems ((ST-L) and (ST-ZL), respectively). A SEM image of the 5% ST-ZL coating is shown in FIG. 2b.

Table 2 also lists experimental parameters and water and oil contact angles measured for glass substrates dip-coated with a Fox-25 silsesquioxane (SSQ) solution and a fluorosilane coating. The SSQ solutions that were used to dip-coat the substrates were: Fox-25 (solids: 15-40% Hydrogen-Silsesquioxane (H-SSQ), solvents: 40-70% Octamethyltrisiloxane, 15-40% hexamethyldisiloxane, and 1-5% Toluene; supplied by Dow Corning); Fox-24 (solids: 15-40% Hydrogen-Silsesquioxane (H-SSQ), solvents: 40-70% Octamethyltrisiloxane, 15-40% hexamethyldisiloxane, and 1-5% Toluene; supplied by Dow Corning); and Fox-14 (solids: 10-30% Hydrogen-Silsesquioxane (H-SSQ), solvents: >60% methylisobutylketone and <1% Toluene; supplied by Dow Corning).

TABLE 2
Contact angles obtained for glass substrates coated dip-coated with Fox-25 SSQ
solution and fluorosilane coating.

| | | particle size | | | | | thickness |
|---|---|---|---|---|---|---|---|
| | chemistry | (nm) | mm/min | post treat | water | oil | (SEM) |
| SiO2 colloidal | 30% ST-L | 40-50 nm | 25 | no | 134 | 98 | |
| nanoparticles only | 30% ST-L | | 100 | no | 134 | 96 | |
| coated with fluorosilane | 5% ST-L | | 25 | no | 135 | 98 | |
| | 5% ST-L | | 100 | no | 134 | 97 | |
| | 30% ST-ZL | 70-100 nm | 25 | no | 138 | 117 | |
| | 30% ST-ZL | | 100 | no | 136 | 117 | |
| | 5% ST-ZL | | 25 | no | 152 | 122 | 240 nm |
| | 5% ST-ZL | | 100 | no | 141 | 120 | 360 nm |
| | 5% ST-ZL | 70-100 nm | 25 | 650 C./1 h | 136 | 102 | |
| silsesquioxane resin | Fox25 | | 100 | no | 115 | 77 | |
| only | 2.5% SiO2 | 25 | 25 | 280 | 154 | 111 | ~250 nm |
| coated with fluorosilane | 2.5% SiO2 | 25 | 25 | 280 | | | |
| SiO2 soot only | 5% SiO2 | 25 | 25 | 280 | 171 | 123 | ~500 nm |
| coated with fluorosilane | 5% SiO2 | 25 | 25 | 280 | | | |
| | 10% SiO2 | 25 | 25 | 280 | 166 | 122 | |
| | 10% SiO2 | 25 | 25 | 280 | | | |

All dip-coated coatings deposited on the samples listed in Table 2 were removed with crockmeter swiping.

### Example 3

The following example describes two processes for fixating the topography of the first layer of silica particles or silica soot with the addition of silsesquioxane. In the first process, a 5 wt % dispersion of SiO₂ soot in an alkaline solution was dip-coated onto alkali aluminosilicate glass substrates at a rate of 25 mm/min. The coated substrate was then air dried. Diluted (50-70 wt %) solutions of SSQ (i.e., Fox-24) were prepared using toluene and applied to the substrates coated with SiO₂ soot by dip-coating. The dip-coating of the substrates with the SSQ solution was repeated to provide a coating that was sufficient to backfill voids in the soot layer. SSQ dip-coating was performed at different speeds. Coated surfaces were then heat treated at 300° C., 350° C. or 550° C. to either cross link (at 300° C. or 350° C.) the SSQ resin or convert the SSQ (at 550° C.) to silica. All samples were then coated with fluorosilane (DC2634). Experimental parameters, including silica dispersions, silica particle size, silica dispersion dipping speed, SSQ concentrations, SSQ solution dipping speeds, and post SSQ dipping heat treatment temperatures are listed in Table 3a. Both oil and water contact angles (CA) were then measured before and after 100 and 1000 crockmeter wipes. The results of contact angle measurements and contact angle loss for both water and oil after 1000 wipes are listed in Table 3b.

As seen in Table 3, some samples (samples A, C, and G) remained nearly super hydrophobic and oleophobic after the crockmeter rubbing tests. Losses in water contact angle of only 12-15% were observed, for example, for Sample SFX47. The results of the crockmeter rubbing tests suggest that the best performance in terms of retention of high contact angles is obtained when the thickness of the SSQ backfilling layer approximates the average thickness of the dip-coated silica soot film. In contrast, thicker SSQ films, which were obtained when the dip-coating solution comprised 70% SSQ or when dip-coating was performed at faster speeds (50 mm/min), yielded contact angles that were indistinguishable from control SSQ coated substrates (Table 2).

TABLE 3
Experimental parameters for samples described in Example 3.

| | | | SSQ Fox coat, | |
|---|---|---|---|---|
| | | SiO₂ | followed by | |
| | | Dipping | fluorosilane | Post |
| | | speed | coating, | treatment |
| Sample | Particles | (mm/min) | dipping speed | temp. (° C.) |
| A | 5% SiO₂ Soot | 25 | 50% Fox24 | 300 |
| | | | 25 mm/min × 2 | |
| B | 5% SiO₂ Soot | 25 | 50% Fox24 | 350 |
| | | | 25 mm/min × 2 | |
| C | 5% SiO₂ Soot | 25 | 50% Fox24 | 550 |
| | | | 25 mm/min × 2 | |
| D | 5% SiO₂ Soot | 25 | 50% Fox24 | 300 |
| | | | 50 mm/min × 2 | |
| E | 5% SiO₂ Soot | 25 | 50% Fox24 | 350 |
| | | | 50 mm/min × 2 | |
| F | 5% SiO₂ Soot | 25 | 50% Fox24 | 550 |
| | | | 50 mm/min × 2 | |
| G | 5% SiO₂ Soot | 25 | 70% Fox24 | 300 |
| | | | 25 mm/min | |
| H | 5% SiO₂ Soot | 25 | 70% Fox24 | 350 |
| | | | 25 mm/min | |
| I | 5% SiO₂ Soot | 25 | 70% Fox24 | 550 |
| | | | 25 mm/min | |

TABLE 3b
Water and oleic contact angles measured for the samples described in Example 3.

| | | | Avg. Water | Ave. Oleic | Avg. Water | Avg. Oleic | | | % oleic |
|---|---|---|---|---|---|---|---|---|---|
| | Avg. | Avg. | CA post | CA post | CA post | CA post | % CA | % CA | CA loss |
| | Water | Oil CA | 100 wipes | 100 wipes | 1000 wipes | 1000 wipes | loss post | loss post | post 1000 |
| Sample | CA deg) | (deg) | (deg) | (deg) | (deg) | (deg) | 100 wipes | 1000 wipes | wipes |
| A | 153 | 116 | 135 | — | 135 | 99 | 12% | 12% | 15% |
| B | 144 | 116 | 136 | 87 | 132 | 83 | 6% | 8% | 28% |
| C | 147 | 117 | 133 | — | 123 | 94 | 10% | 16% | 20% |
| D | 143 | 108 | 127 | — | 120 | 83 | 11% | 16% | 23% |
| E | 142 | 109 | 134 | — | 123 | 84 | 6% | 13% | 23% |
| F | 142 | 106 | 124 | — | 126 | 85 | 13% | 11% | 20% |
| G | 152 | 111 | 130 | — | 133 | 89 | 14% | 13% | 20% |
| H | 144 | 116 | 136 | — | 121 | 86 | 6% | 16% | 26% |
| I | 147 | 113 | 131 | — | 121 | 81 | 11% | 18% | 28% |

While typical embodiments have been set forth for the purpose of illustration, the foregoing description should not be deemed to be a limitation on the scope of the disclosure or appended claims. Accordingly, various modifications, adaptations, and alternatives may occur to one skilled in the art without departing from the spirit and scope of the present disclosure or appended claims.

1. A transparent substrate having a durable surface that exhibits at least one of hydrophobicity and oleophobicity, wherein the durable surface comprises:
a. a first layer disposed on the transparent substrate, the first layer comprising inorganic nanoparticles having a first layer topography and an average agglomerate size or an average particle size; and
b. a fluorosilane coating disposed over the first layer, wherein the durable surface has one of an oil contact angle and a water contact angle after 100 wipes that varies by less than about 20% from an initial contact angle of the durable surface measured before wiping.

2. The transparent substrate of claim 1, further including an immobilizing layer disposed between the first layer and the fluorosilane coating, wherein the immobilizing layer comprises at least one of an inorganic oxide and a silsesquioxane.

3. The transparent substrate of claim 2, wherein the immobilizing layer has a topography that substantially conforms to the first layer topography.

4. The transparent substrate of claim 2, wherein the immobilizing layer comprises a silsesquioxane.

5. The transparent substrate of claim 2, wherein the immobilizing layer comprises at least one inorganic oxide and has a thickness that is within about 20% of an average agglomerate size or an average particle size of the inorganic nanoparticles in the first layer.

6. The transparent substrate of claim 1, wherein the inorganic nanoparticles comprise at least one of zinc oxide, silica, ceria, alumina, and combinations thereof.

7. The transparent substrate of claim 1, wherein an area covered by droplets transferred to the durable surface per finger touch is less than about 20% of a total area of the durable surface of the transparent substrate contacted by the finger.

8. The transparent substrate of claim 1, wherein the transparent substrate has a transmittance of greater than about 70% after 100 wipes of the durable surface.

9. The transparent substrate of claim 1, wherein the transparent substrate has a haze of less than about 80% after 100 wipes of the durable surface.

10. The transparent substrate of claim 1, wherein the durable surface has a gloss of greater than about 60% after 100 wipes of the durable surface.

11. The transparent substrate of claim 1, wherein the transparent substrate comprises one of an alkali aluminosilicate glass and an alkali aluminoborosilicate glass.

12. The transparent substrate of claim 11, wherein the alkali aluminosilicate glass comprises: about 61 mol % to about 75 mol % SiO₂; about 7 mol % to about 15 mol % Al₂O₃; 0 mol % to about 12 mol % B₂O₃; about 9 mol % to about 21 mol % Na₂O; 0 mol % to about 4 mol % K₂O; 0 mol % to about 7 mol % MgO; and 0 mol % to about 3 mol % CaO.

13. The transparent substrate of claim 11, wherein the alkali aluminosilicate glass comprises: about 60 mol % to about 70 mol % SiO₂; about 6 mol % to about 14 mol % Al₂O₃; 0 mol % to about 15 mol % B₂O₃; 0 mol % to about 15 mol % Li₂O; 0 mol % to about 20 mol % Na₂O; 0 mol % to about 10 mol % K₂O; 0 mol % to about 8 mol % MgO; 0 mol % to about 10 mol % CaO; 0 mol % to about 5 mol % ZrO₂; 0 mol % to about 1 mol % SnO₂; 0 mol % to about 1 mol % CeO₂; less than about 50 ppm As₂O₃; and less than about 50 ppm Sb₂O₃; and wherein 12 mol %≦Li₂O+Na₂O+K₂O≦20 mol % and 0 mol %≦MgO+CaO≦10 mol %.

14. The transparent substrate of claim 11, wherein the alkali aluminoborosilicate glass comprises greater than 50 mol % SiO₂, and wherein
$$\frac{{Al}_{2} {O}_{3} ( mol \% ) + {B}_{2} {O}_{3} ( mol \% )}{\sum alkali metal modifiers ( mol \% )} > 1 ,$$
where the alkali metal modifiers are alkali metal oxides.

15. The transparent substrate of claim 11, wherein the transparent substrate is chemically strengthened.

16. The transparent substrate of claim 1, wherein the transparent substrate is one of a touch screen and a protective cover glass for at least one of a hand held electronic device, an information-related terminal, and a touch sensor device.

17. The transparent substrate of claim 1, wherein the durable surface has a topography that substantially conforms to the first layer topography.

18. The transparent substrate of claim 1, wherein the first layer further comprises a silsesquioxane.

19. A transparent substrate having a durable surface that exhibits at least one of hydrophobicity and oleophobicity, the durable surface comprising:
a. a first layer of inorganic nanoparticles disposed on the transparent substrate, the inorganic nanoparticles having a first layer topography and an average agglomerate size or an average particle size;
b. an immobilizing layer disposed over the first layer, wherein the immobilizing layer comprises at least one inorganic oxide and has a thickness that is within about 20% of the average particle size of the inorganic nanoparticles in the first layer; and
c. a fluorosilane coating disposed over the immobilizing layer, wherein the durable surface has one of an oil contact angle and a water contact angle after 100 wipes that varies by less than about 20% from an initial contact angle measured before wiping.

20. The transparent substrate of claim 19, wherein the immobilizing layer has a topography that substantially conforms to the first layer topography.

21. The transparent substrate of claim 19, wherein the immobilizing layer comprises a silsesquioxane.

22. The transparent substrate of claim 19, wherein the immobilizing layer comprises at least one inorganic oxide.

23. The transparent substrate of claim 19, wherein the inorganic nanoparticles comprise at least one of zinc oxide, silica, ceria, alumina, and combinations thereof.

24. The transparent substrate of claim 19, wherein the transparent substrate comprises one of an alkali aluminosilicate glass and an alkali aluminoborosilicate glass.

25. The transparent substrate of claim 24, wherein the transparent substrate is chemically strengthened.

26. A transparent substrate having a durable surface that exhibits at least one of hydrophobicity and oleophobicity, the durable surface comprising:
a. at least one layer disposed on the transparent substrate comprising a plurality of inorganic nanoparticles and a silsesquioxane; and
b. a fluorosilane coating disposed over the at least one layer, wherein the durable surface has one of an oil contact angle and a water contact angle after 100 wipes that varies by less than about 20% from an initial contact angle measured before wiping.

27. The transparent substrate of claim 26, wherein the inorganic nanoparticles comprise at least one of zinc oxide, silica, ceria, alumina, and combinations thereof.

28. The transparent substrate of claim 26, wherein the transparent substrate comprises one of an alkali aluminosilicate glass and an alkali aluminoborosilicate glass.

29. The transparent substrate of claim 28, wherein the transparent substrate is chemically strengthened.

30. A method of making a transparent substrate having a durable surface that exhibits at least one of hydrophobicity and oleophobicity, the method comprising the steps of:
a. providing a transparent substrate;
b. forming a first layer on a surface of the transparent substrate, the first layer comprising a plurality of inorganic nanoparticles and having a first layer topography;
c. optionally forming an immobilizing layer on the first layer, the immobilizing layer comprising at least one of a silsesquioxane and an inorganic oxide; and
d. forming an outer layer comprising a fluorosilane on one of the first layer and immobilizing layer to form the durable surface, wherein the durable surface has one of an oil contact angle and a water contact angle after 100 wipes that varies by less than about 20% from an initial contact angle measured before wiping.

31. The method of claim 30, wherein the step of forming the first layer comprises coating the transparent substrate with a dispersion, the dispersion comprising the plurality of inorganic nanoparticles, by one of spin coating, dip coating, and spray coating.

32. The method of claim 31, wherein the dispersion further comprises a silsesquioxane.

33. The method of claim 30, wherein the step of forming the immobilizing layer comprises depositing the silsesquioxane on the first layer by one of spin coating, dip coating, and spray coating.

34. The method of claim 30, wherein the step of forming the immobilizing layer comprises sputtering the inorganic oxide onto the first layer.

35. The method of claim 34, wherein the immobilizing layer has a thickness that is within about 20% of an average agglomerate size or an average particle size of the inorganic nanoparticles in the first layer.

36. The method of claim 30, wherein the inorganic nanoparticles comprise at least one of zinc oxide, silica, ceria, alumina, and combinations thereof.

37. The method of claim 30, wherein step of providing the transparent substrate comprises providing a transparent substrate comprising one of an alkali aluminosilicate glass and an alkali aluminoborosilicate glass.

38. The method of claim 37, wherein the transparent substrate is chemically strengthened.

39. The method of claim 30, wherein the immobilizing layer has a topography that substantially conforms to the first layer topography.

40. The method of claim 30, wherein the step of optionally forming an immobilizing layer on the first layer further comprises annealing the immobilizing layer.
